(19) United States
(12) Patent Application Publication
(10) Pub. No.: US 2008/0277645 A1
(43) Pub. Date: Nov. 13, 2008

(54) Ferromagneic Influence on Quantum Dots

(75) Inventors: Charles Gould, Wurzburg (DE); Georg Schmidt, Lindenflur (DE); Laurens W. Molenkamp, Wurzburg (DE)

Correspondence Address: BROWDY AND NEIMARK, P.L.L.C.;624 NINTH STREET, NW, SUITE 300, WASHINGTON, DC, 20001-5303, US

(73) Assignee: ETeCH AG, Schlieren (CH)

(21) Appl. No.: 11/579,653

(22) PCT Filed: May 6, 2005
(86) PCT No.: PCT/CH2005/000255

§ 371 Date: Nov. 6, 2006

Related U.S. Application Data
(60) Provisional application No. 60/568,852, filed on May 7, 2004.

(51) Int. Cl. H01L 29/06; H01L 21/00

(52) U.S. Cl. 257/14; 438/3; 257/E21.001; 257/E29.071

(57) ABSTRACT

A semiconductor magnetic body comprises a layer (11 15) intended to trap electrons, wherein said layer (11 15) is surrounded on both sides by a magnetic layer (16, 17). This leads to the creation of ferromagnetic character in spatially limited regions of electronic elements such as but not limited to quantum dots, where this creation is achieved using magnetic materials which do not compositionally form part of the region but are rather contained in the zone or zones adjacent to the region.

### BACKGROUND OF THE INVENTION

In the production of electronic circuits based upon the principles of spintronics, that is, using the location and sign of the spin of the electron rather than its charge as the pre-eminent factor under control, it is of extreme importance to provide a means to selectively inject and detect electrons with a well-defined spin into a non-magnetic semiconductor. Furthermore, it is often desirable to create regions of material where electrons can be selectively contained and released as the computational requirements of the circuits require—so-called magnetic ‘quantum dots’.

Previously, it was known that “spin filtering” should very well be achievable using semi-magnetic quantum dots fabricated from II-VI materials. However, such a means of spin injection still involves the application of ant external magnetic field since the semi-magnetic alloys are themselves not ferromagnets, but instead very strong paramagnets.

### SUMMARY OF THE INVENTION

We have now fabricated such semi-magnetic quantum dots using a novel procedure. Hitherto such quantum dots have been artificially made by the deposition of materials of selected compositions and then selectively etching. Hitherto, also, the material which forms the quantum dot has beneficially contained a magnetic element, preferably manganese, to provide an influence on the electron within the dot leading to Zeeman splitting, an important feature of spintronics.

The present invention involves providing the magnetic influence by arranging for the magnetic material, for example manganese, to be contained not within the layer of the dot intended to trap the electron, but in the surrounding layer(s). By this means a greater amount of manganese can be included in the entire structure. This allows a higher and significant magnetic influence on the dots.

Furthermore, and more importantly, our results show that even for barrier layers that are not ferromagnetic, the quantum dot levels are split in the absence of an external magnetic field. This means that a quantum dot can be employed as a spin filter without needing an external magnetic field.

This effect can be seen e.g., in CdSe quantum dots formed in a ZnBeMnSe layer sandwiched between ZnSe layers.

It is an object of the invention to provide a method to produce such electronic structures, especially with quantum dots.

The creation of ferromagnetic character in spatially limited regions of electronic elements such as but not limited to quantum dots, where this creation is achieved using magnetic materials which do not compositionally form part of the region but are rather contained in the zone or zones adjacent to the region.

The invention will now be described by the following description of embodiments according to the invention, with reference to the drawing, in which:

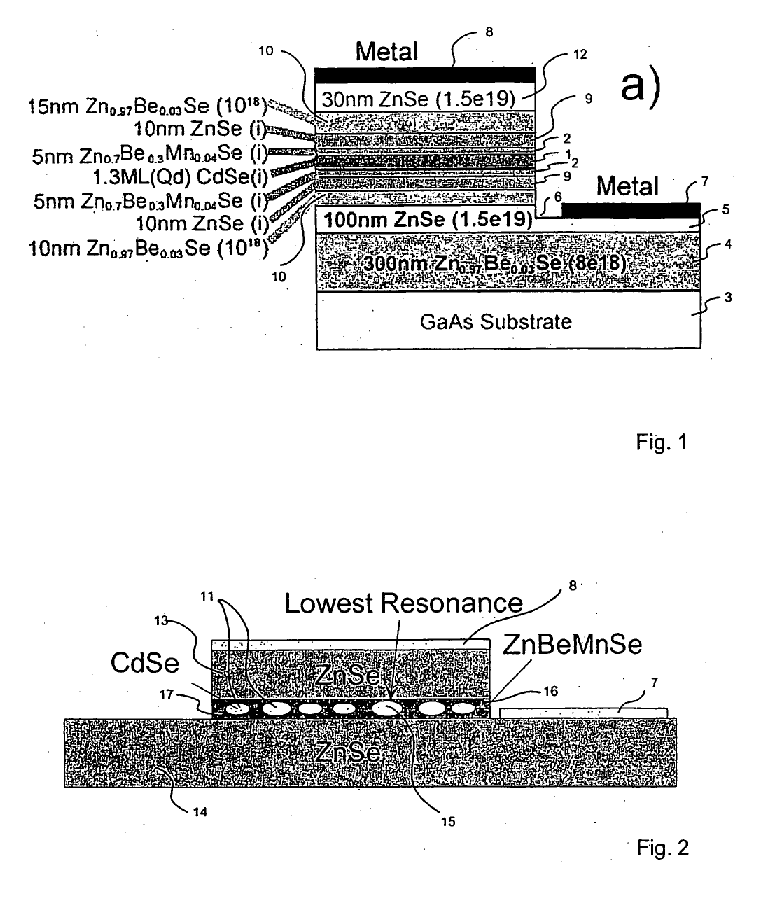

FIG. 1 shows a schematic view of a device according to the invention showing the geometry of the layers and contacts;

FIG. 2 shows a principle view of a device according to the invention;

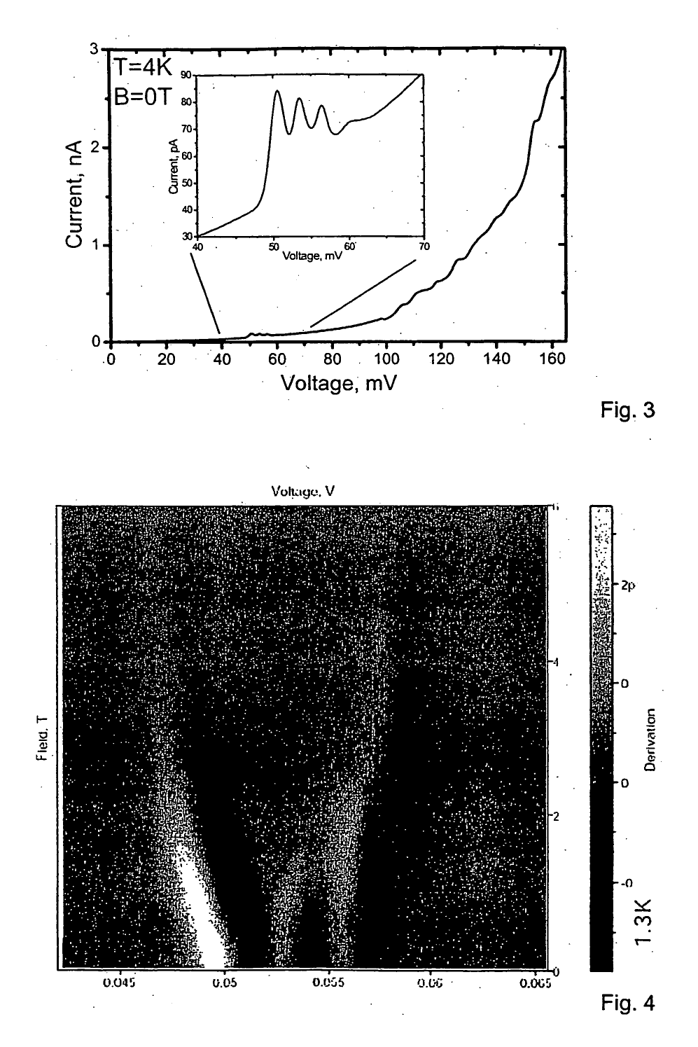

FIG. 3 shows a current-voltage curve of a sample device according to an embodiment of the invention at 4K and in the absence of magnetic field;

FIG. 4 shows the derivative of the current as a function of bias voltage, here for the 1.3K current parallel to field case; and

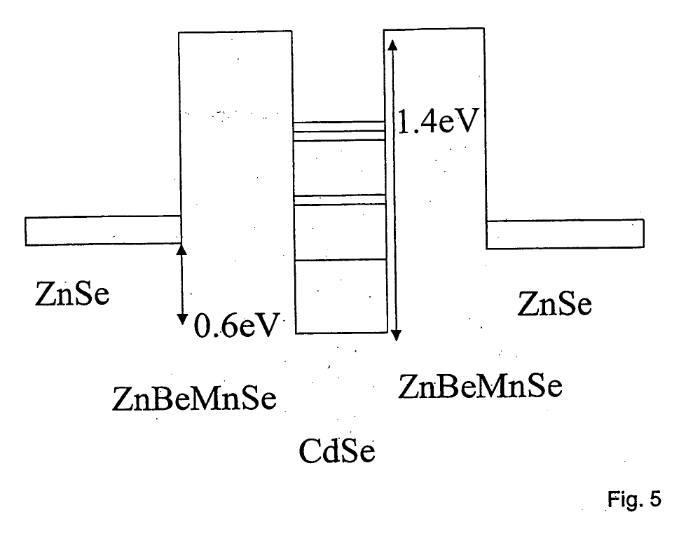

FIG. 5 shows the splitting of the tunneling levels in the well.

The sample consist of a 1.3 monolayer of a CdSe layer (reference numeral 1) imbedded into a 10 nm thick Zn.7Be.3Mn.04Se barrier layer (two 5 nm layers 2) contacted by appropriately doped injector and collector layer stacks. Because of the strain induced by the lattice mismatch between the CdSe and the Zn.7Be.3Mn.04Se, the CdSe reorganizes itself into fairly uniform islands 11 of material as can be seen in FIG. 2, which play the role of quantum dots in our structures. The full layer structure can be seen in FIG. 1.

The GaAs substrate 3 has received a 300 nm Zn_{0.97}Be_{0.03}Se (8e18) layer 4 being topped by a 100 nm ZnSe (1.5e19) layer 5. There is a free surface 6 on one side of the device, covered in part by a second metal contact 7. A first metal contact 8 is provided on the top of the pillar structure with the additional layers 9 and 10, symmetrically disposed around the CdSe layer 1. 100 nm layer 5 has a 30 nm layer counterpart 12 just under the first metal contact 8.

The sample is then patterned into a ˜100 micrometer square vertical resonant tunneling structure using optical lithography. A schematic of the resulting transport structure is shown in FIG. 2. The quantum dots 11 comprise one region 15 having the lowest resonance, shown as the biggest structure in the schematic view of FIG. 2. These areas 11, 15 are surrounded by the layers 16 and 17, here identical with a concentration of manganese. This may also be a material showing directly or in the used compound ferromagnetic properties. This important layer structure (layers 16 and 17 with zones 11, 15 inside layer 1) is surrounded by layers 13 and 14 and comprises metal contacts 7 and 8.

Transport measurements are taken in the form of current-voltage measurements at various (low) temperatures with and without an applied magnetic field. As is well known from previous work on non-magnetic self-assembled quantum dots, despite the fact that the mesa contains a large number of dots, the transport is often dominated by one of these which, do to statistical variations in the sample, has the highest tunneling transmission probability. This is the case in the sample under discussion here. FIG. 3 shows a current-voltage curve of the sample at 4K and in the absence of magnetic field. The small feature at around 50 mV and blown up in the inset, is associated with tunneling through this individual dots, while the multiple resonances above 100 mV come from tunneling through other dots. The experimental investigations focused on the feature associated with the single dot, and the bulk of these experimental results are present in the attached description, showing the current trough the device as a function of bias voltage and magnetic field for various field strengths and orientations and at different temperatures.

The main experimental observations can be most clearly seen by looking at the derivative of the current as a function of bias voltage, as in the image of FIG. 4 for the 1.3K current parallel to field case.

We see firstly, that the splitting of the resonance as a function of an external applied magnetic field follows a Brillouin like behavior indicating that the levels in the dots are in some way couple to the manganese system in the well. And secondly, that the splitting between two spin-split levels in the dots remains finite as the external field is reduced to zero. Given that the Zn.7Be.3Mn.04Se is paramagnetic, and not ferromagnetic in nature, this splitting at zero field indicated that the dot states must couple to the surrounding magnetic state in such a way as to for a local magnetic object with properties difference from that of the surrounding medium.

This coupling will lead to a splitting of the tunneling levels in the well as shown in FIG. 5, which can be used to select between different spin states in an eventual spintronics device.

1. The creation of ferromagnetic character in spatially limited regions of electronic elements such as but not limited to quantum dots, where this creation is achieved using magnetic materials which do not compositionally form part of the region but are rather contained in the zone or zones adjacent to the region.

2. A semiconductor magnetic body comprising a layer (1, 11 15) intended to trap electrons, wherein said layer (1, 11 15) is surrounded on both sides by a magnetic layer (16, 17).

3. The semiconductor magnetic body according to claim 2, wherein the layer (1, 11, 15) intended to trap electrons comprises a CdSe monolayer and the magnetic layer comprises manganese or is a ZnBeMnSe layer, the magnetic body further comprising ZnSe layers (13 or 14) on both sides of the magnetic layers (16 respectively 17) and metal contacts (8 respectively 7).
